(19) United States
(12) Patent Application Publication
(10) Pub. No.: US 2025/0183081 A1
(43) Pub. Date: Jun. 5, 2025

(54) SUBSTRATE PROCESSING DEVICE AND POSITIONING METHOD OF CONVEYANCE ARM

(71) Applicant: Tokyo Electron Limited, Tokyo (JP)

(72) Inventor: Junya MIYAMATSU, Yamanashi (JP)

(21) Appl. No.: 19/050,019

(22) Filed: Feb. 10, 2025

Related U.S. Application Data
(63) Continuation of application No. PCT/JP2024/023125, filed on Jun. 26, 2024.

(30) Foreign Application Priority Data
Jul. 5, 2023 (JP) 2023-110562

(51) Int. Cl. H01L 21/68; H01L 21/67; H01L 21/687

(52) U.S. Cl. CPC H01L 21/681; H01L 21/67167; H01L 21/68707

(57) ABSTRACT

The present disclosure relates to a substrate processing apparatus for processing a substrate, the apparatus comprises: a transfer module for transferring the substrate therein; a transfer arm disposed inside the transfer module and provided with at least one holding arm for holding the substrate; and at least one processing module connected to the transfer module and comprising at least one processing chamber for processing the substrate therein. The at least one processing chamber comprises: a substrate support having a support surface for supporting the substrate; a plate member disposed above the substrate support; and a lateral wall unit configuring an inner surface of the at least one processing chamber, wherein a processing space surrounded by the substrate support, the plate member, and the lateral wall unit is formed in the at least one processing chamber, and the transfer arm comprises a sensor for positioning the transfer arm.

### CROSS-REFERENCE TO RELATED APPLICATIONS

This application is a bypass continuation application of International Application No. PCT/JP2024/023125 having an international filing date of Jun. 26, 2024 and designating the United States, the International Application being based upon and claiming the benefit of priority from Japanese Patent Application No. 2023-110562 filed on Jul. 5, 2023, each of which is hereby incorporated by reference in its entirety.

### TECHNICAL FIELD

The present disclosure relates to a substrate processing apparatus and a positioning method of a transfer arm.

### BACKGROUND

Japanese Laid-open Patent Publication No. H7 (1995)-074229 discloses a technology for setting the position of a substrate transfer machine in a semiconductor manufacturing device using a reflective distance detection sensor. The semiconductor substrate position detection device disclosed in Japanese Laid-open Patent Publication No. H7 (1995)-074229 uses a jig having a pin vertically disposed at the center of a plate having the same shape as a semiconductor substrate, and the reflective distance detection sensor. The reflective distance detection sensor detects a side surface of the jig, reads the longitudinal position of the semiconductor substrate, and then detects the center of the pin to detect the left/right angular position of the substrate transfer machine and the distance to the pin.

### SUMMARY

The technology described herein provides proper positioning of a transfer arm within a processing chamber.

The present disclosure relates to a substrate processing apparatus for processing a substrate, the apparatus comprises: a transfer module for transferring the substrate therein; a transfer arm disposed inside the transfer module and provided with at least one holding arm for holding the substrate; and at least one processing module connected to the transfer module and comprising a processing chamber for processing the substrate therein. The processing chamber comprises: a substrate support having a support surface for supporting the substrate; a plate member disposed above the substrate support; and a lateral wall unit configuring an inner surface of the processing chamber, wherein a processing space surrounded by the substrate support, the plate member, and the lateral wall unit is formed in the processing chamber; and the transfer arm comprises a sensor for positioning the transfer arm based on distances, in the processing space, from the transfer arm to the substrate support, the plate member, and the lateral wall unit.

### BRIEF DESCRIPTION OF THE DRAWINGS

FIG. 1 is a plan view of an outline of a configuration of a wafer processing device according to an embodiment of the present disclosure.

FIG. 2 is a perspective view of a configuration of a transfer arm of a transfer module.

FIG. 3 is a schematic plan view of an example of the configuration of the effector during positioning.

FIG. 4 is a schematic explanatory view of a positioning method in a processing module.

FIG. 5 is a schematic explanatory view of a positioning method in a processing module.

FIG. 6 is a schematic explanatory view of the rotation direction of a sensor.

### DETAILED DESCRIPTION

In the manufacturing process of semiconductor devices, a process of etching and removing an oxide film formed on the surface of a semiconductor wafer (hereinafter sometimes referred to as a “wafer”) is performed. For example, the etching process of the oxide film is performed by chemical oxide removal (COR) processing and post heat treatment (PHT) processing.

Herein, in a substrate processing system, the COR processing or the PHT processing may each be performed in a different processing module. In order to properly process the wafer in each processing module, it is necessary to accurately transfer the wafer to be processed to an appropriate position, such as a mounting table. For this reason, a task called teaching (also called positioning) is performed in which the transfer position of the wafer on the mounting table or the like is registered as a target position in the form of a position coordinate on the transfer arm that transfers the wafer to the processing module.

Japanese Laid-open Patent Publication No. H7 (1995)-074229 mentioned above discloses that the position of a semiconductor substrate is automatically detected by using a jig and a sensor. This enables shortening teaching task time, improving work efficiency, and improving performance.

However, in the technique disclosed in Japanese Laid-open Patent Publication No. H7 (1995)-074229, the detection of a semiconductor substrate position is performed two-dimensionally (for example, in an XY plane direction), and teaching is not performed three-dimensionally (for example, in an XYZ spatial direction). In recent years, it has become known that in processing modules, members included in a chamber, such as a substrate support (also referred to as a stage) and a shower plate, are configured to be moveable. Conventionally, the displacement of the substrate support and the shower plate has been adjusted based on the process conditions of each process, such as the COR processing or the PHT processing. This may lead to differences between device models or between a plurality of processing modules in the same device. In addition, there is also an issue such as increased process startup period to execute adjustments.

In the processing modules of recent substrate processing systems, even when a wafer is mounted at the center of the stage, the process results are affected by gas flow or heat from the side walls of the chamber. Hence, installation errors, including those in the height direction of each member such as the stage and shower plate, have a significant effect on the process. Accordingly, in order to transfer the wafer to an optimal position within the process space, it is required to guide the transfer arm to an arbitrary teaching position in the three-dimensional space within a processing chamber.

The technology described herein has been made in consideration of the above circumstances, and appropriately positions the transfer arm within the processing chamber. Hereinafter, a wafer processing device and a positioning method according to the present embodiment will be described with reference to the drawings. In addition, in this specification and drawings, elements having substantially the same functional configurations are denoted by the same reference numerals, and redundant descriptions thereof will be omitted.

### <Wafer Processing Device>

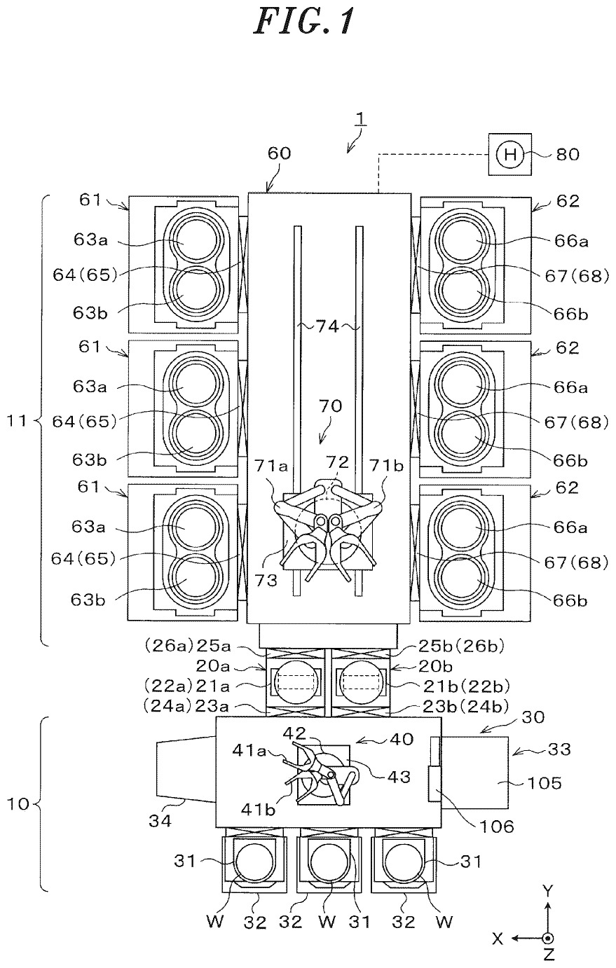

First, the configuration of the wafer processing device according to the present embodiment will be described. FIG. 1 is a plan view of an outline of a configuration of a wafer processing device according to an embodiment of the present disclosure. In the present embodiment, a case will be described in which a wafer processing device 1 includes each processing module for performing substrate processing, cleaning processing, and aligner processing on a wafer W as a substrate. In addition, the module configuration of the wafer processing device 1 of an embodiment of the present disclosure is not limited thereto, and may be selected arbitrarily. In this specification, the wafer processing device 1 may be illustrated and described with the width direction thereof being an X-axis direction, the length direction thereof being a Y-axis direction, and the height direction thereof being a Z-axis direction.

As illustrated in FIG. 1, the wafer processing device 1 has an atmospheric unit 10 and a reduced pressure unit 11 that are integrally connected via load lock modules 20a and 20b.

The atmospheric unit 10 includes a plurality of atmospheric modules that perform desired processing on the wafer W under atmospheric pressure. The reduced pressure unit 11 includes a plurality of reduced pressure modules that perform desired processing on the wafer W under a reduced pressure atmosphere.

The load lock module 20a delivers the wafer W transferred from a loader module 30 described later of the atmospheric unit 10 to a transfer module 60 described later of the reduced-pressure unit 11, thereby temporarily holding the wafer W. The load lock module 20a has an upper stocker 21a and a lower stocker 22a that hold two wafers W vertically.

The load lock module 20a is connected to a loader module 30, which will be described later, via a gate 24a provided with a gate valve 23a. The gate valve 23a ensures airtightness between the load lock module 20a and the loader module 30 while allowing communication therebetween. In addition, the load lock module 20a is connected to the transfer module 60, which will be described later, via a gate 26a provided with a gate valve 25a. The gate valve 25a ensures airtightness between the load lock module 20a and the transfer module 60 while allowing communication therebetween.

The load lock module 20a is connected to an air supply unit (not shown) that supplies gas and an exhaust unit (not shown) that exhausts gas, and is configured so that the interior may be switched between atmospheric pressure and reduced pressure atmosphere by the air supply unit and the exhaust unit. In other words, the load lock module 20a is configured to allow the wafer W to be appropriately transferred between the atmospheric unit 10 under atmospheric pressure and the reduced pressure unit 11 under a reduced pressure atmosphere.

In addition, the load lock module 20b has the same configuration as the load lock module 20a. In other words, the load lock module 20b has an upper stocker 21b, a lower stocker 22b, a gate valve 23b and a gate 24b on a loader module 30 side, and a gate valve 25b and a gate 26b on a transfer module 60 side.

In addition, the number and disposition of the load lock modules 20a, 20b are not limited to those in the present embodiment, but may be set arbitrarily.

The atmospheric unit 10 has the loader module 30 provided with a wafer transfer mechanism 40 described later, a load port 32 on which a FOUP 31 capable of storing a plurality of wafers W is mounted, a wafer cleaning module 33 that removes fluorine from the wafer W, and an aligner module 34 that adjusts an orientation of the horizontal direction of the wafer W.

The loader module 30 serving as a transfer device for the wafer W has an internal rectangular housing, the interior of which is maintained at atmospheric pressure. A plurality of, for example, three load ports 32 are arranged side by side on one side surface that configures a long side of the housing of the loader module 30. On the other side surface configuring the longer side of the housing of the loader module 30, the load lock modules 20a and 20b are arranged side by side. An atmospheric substrate processing apparatus (for example, a wafer cleaning module, a wafer cooling module, an optical film thickness measuring device, or the like) 33 may be provided on one side surface that configures a short side of the housing of the loader module 30. The aligner module 34 is provided on the other side surface that configures the short side of the housing of the loader module 30.

In addition, the number or disposition of the load ports 32 and the aligner modules 34 are not limited to those in this embodiment, but may be designed arbitrarily. For example, a plurality of wafer cleaning modules 33 may be provided, and may be provided on both sides with the load lock modules 20a, 20b therebetween.

The FOUP 31 accommodates a plurality of wafers W, for example, 25 wafers per lot, stacked in multiple stages at equal intervals. In addition, the interior of the FOUP 31 mounted on the load port 32 is filled with, for example, air or nitrogen gas and is sealed.

The atmospheric substrate processing apparatus 33 may cool the wafer W after the COR processing or the PHT processing, and may measure the film thickness of the wafer W before and after the COR processing.

The aligner module 34 rotates the wafer W to adjust an orientation of the horizontal direction. Specifically, when wafer processing is performed on each of the plurality of wafers W, the aligner module 34 is adjusted so that the orientation from the horizontal direction to a reference position (for example, notch position) is the same for each wafer processing.

The wafer transfer mechanism 40 for transferring the wafer W is provided inside the loader module 30. The wafer transfer mechanism 40 has a transfer arm 41 (41a, 41b) that holds and moves the wafer W, a rotating table 42 that rotatably supports the transfer arm 41, and a rotating mounting table 43 on which the rotating table 42 is mounted. The wafer transfer mechanism 40 is configured to be movable in a longitudinal direction inside the housing of the loader module 30.

The reduced pressure unit 11 has a transfer module 60 that simultaneously transfers two wafers W, a substrate processing module 61 that performs, for example, the COR processing on the wafer W transferred from the transfer module 60, and a substrate processing module 62 that performs, for example, the PHT processing. The interiors of the transfer module 60, the substrate processing module 61, and the substrate processing module 62 are each maintained at a reduced pressure atmosphere. For the transfer module 60, a plurality of substrate processing modules 61 and substrate processing modules 62, for example, three, are provided.

The transfer module 60 has an internal rectangular housing, and is connected to the load lock modules 20a and 20b via the gate valves 25a, 25b as described above. The transfer module 60 has an internally rectangular housing, and transfers the wafer W carried from the load lock module 20a sequentially to one substrate processing module 61 and one substrate processing module 62 to perform, for example, the COR processing and the PHT processing, and then carry out the wafer W to the atmospheric unit 10 via the load lock module 20b.

Inside the substrate processing module 61, two stages 63a, 63b are provided on which two wafers W are mounted side by side in the horizontal direction. The substrate processing module 61 performs, for example, the COR processing on two wafers W simultaneously by mounting the wafers W side by side on the stages 63a, 63b. In addition, the substrate processing module 61 is connected to the air supply unit (not shown) that supplies processing gas, purge gas, and the like, and the exhaust unit (not shown) that exhausts gas.

In addition, the substrate processing module 61 is connected to the transfer module 60 via a gate 65 provided with a gate valve 64. The gate valve 64 ensures airtightness between the transfer module 60 and the substrate processing module 61 while allowing communication therebetween.

Inside the substrate processing module 62, two stages 66a, 66b are provided on which two wafers W are mounted side by side in the horizontal direction. The substrate processing module 62 performs, for example, the PHT processing on two wafers W simultaneously by mounting the wafers W side by side on the stages 66a, 66b. In addition, the substrate processing module 62 is connected to the air supply unit (not shown) that supplies gas and the exhaust unit (not shown) that exhausts gas.

In addition, the substrate processing module 62 is connected to the transfer module 60 via a gate 68 provided with a gate valve 67. The gate valve 67 ensures airtightness between the transfer module 60 and the substrate processing module 62 while allowing communication therebetween.

A wafer transfer mechanism 70 for transferring the wafer W is provided inside the transfer module 60. The wafer transfer mechanism 70 has a transfer arm 71 (71a, 71b) that holds and moves two wafers W, a rotating table 72 that rotatably supports the transfer arms 71a, 71b, and a rotating mounting table 73 on which the rotating table 72 is mounted. In addition, inside the transfer module 60, a guide rail 74 is provided which extends in the longitudinal direction of the transfer module 60. The rotating mounting table 73 is provided on the guide rail 74, and the wafer transfer mechanism 70 is configured to be movable along the guide rail 74.

In the transfer module 60, the transfer arm 71a receives the two wafers W held in the upper stocker 21a and the lower stocker 22a in the load lock module 20a and transfers the same to the substrate processing module 61. In addition, for example, two wafers W that have been subjected to the COR processing are held by the transfer arm 71a and transferred to the substrate processing module 62. In addition, the transfer arm 71b holds two wafers W that have been subjected to, for example, the PHT processing, and carries out the same to the load lock module 20b.

The aforementioned wafer processing device 1 is provided with a controller 80. The controller 80 is, for example, a computer provided with a CPU, a memory, etc., and has a program storage (not shown). The program storage stores a program for controlling the processing of the wafer W in the wafer processing device 1. The program may control the transfer arm 71 of the wafer processing device 1 and a sensor provided on the transfer arm 71. In addition, a correction calculation unit for control purposes may be provided. The program may be recorded on a computer-readable storage medium H and installed into the controller 80 from the storage medium H. In addition, the storage medium H may be either transient or non-transient.

### <Configuration of Transfer Arm>

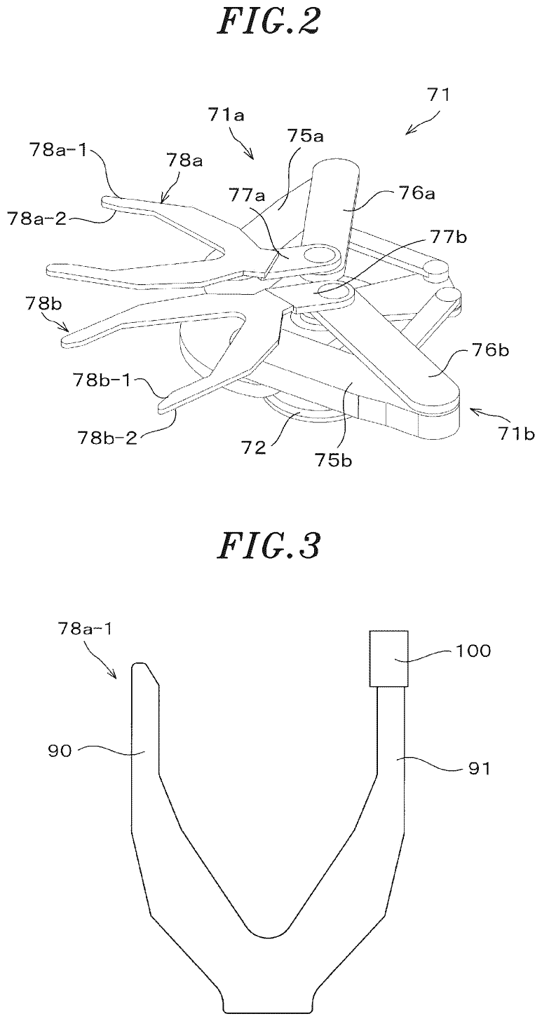

FIG. 2 is a perspective view of a schematic configuration of the transfer arm 71. As illustrated in FIG. 2, the transfer arm 71a has a first arm 75a having one end rotatably connected to the rotating table 72, a second arm 76a having one end rotatably connected to the other end of the first arm 75a, and a third arm 77a having one end rotatably connected to the other end of the second arm 76a. A multi-stage effector 78a serving as a pick for holding the wafer W is connected to the other end of the third arm 77a. The multi-stage effector 78a is configured by stacking a plurality of effectors in a multi-stage manner, and the number of stages is arbitrary. For example, the multi-stage effector 78a may be a two-stage type, in which case the multi-stage effector 78a may be configured by an upper stage effector 78a-1 and a lower stage effector 78a-2.

In addition, the transfer arm 71b has a first arm 75b having one end rotatably connected to the rotating table 72, a second arm 76b having one end rotatably connected to the other end of the first arm 75b, and a third arm 77b having one end rotatably connected to the other end of the second arm 76b. A multi-stage effector 78b serving as a pick for holding the wafer W is connected to the other end of the third arm 77b. The multi-stage effector 78b is configured by stacking a plurality of effectors in a multi-stage manner, and the number of stages is arbitrary. For example, the multi-stage effector 78b may be a two-stage type, in which case the multi-stage effector 78b may be configured by an upper stage effector 78b-1 and a lower stage effector 78b-2.

FIG. 3 is a schematic plan view of an example of the configuration of the multi-stage effectors 78a (78a-1, 78a-2) and 78b (78b-1, 78b-2) during positioning, and illustrates the upper-stage effector 78a-1 in a plan view as a representative of the effectors of each transfer arm 71a, 71b. As illustrated in FIG. 3, the upper effector 78a-1 includes claws 90 and 91 that are bifurcated about the connection position with the third arm 77a. A sensor 100 is installed to the tip of at least one of the claws 90 (and/or 91).

The sensor 100 may be, for example, a photoelectric sensor that measures distance by irradiating an object with laser light and detecting the light that is reflected back. In addition, the sensor 100, which is a photoelectric sensor, may be configured to be rotatable 360° around an axis (in a ZY plane direction) with an extension direction of the transfer arm 71 as the axis. In other words, the sensor 100 may be configured to be able to irradiate the laser light in all three dimensional directions in accordance with the extension of the transfer arm 71. When the transfer arm 71 is inserted into a processing module such as the substrate processing module 61 or the substrate processing module 62, the sensor 100 may measure the distance to members such as the substrate support (stage), plate member (gas supply plate), and lateral wall unit of each processing module. In addition, the sensor 100 may also measure the shapes of various members, such as the outer shape of the substrate support and the outer shape of the plate member. In other words, by laser scanning members such as the substrate support, plate member, and lateral wall unit, it is possible to specify positions such as the height position, central position of the members, and the spatial central position of the processing space formed within the processing module. In addition, the plate member in each processing module may include an upper electrode assembly.

In addition, the sensor 100 may be configured to be detachable. In other words, the sensor 100 may be installed in the effector during positioning and separated during substrate processing. In addition, in the configuration according to this embodiment, it is preferable that at least one sensor 100 is installed in each of the multi-stage effectors 78a and 78b. In the multi-stage effectors 78a, 78b, the sensor 100 may be installed in either the upper or lower stage effector. The installation position of the sensor 100 on the multi-stage effectors 78a, 78b is arbitrary and is not limited to the position illustrated. For example, it may be at a position such as the root of the claw unit 90 (and/or 91). However, it is required to specify in advance the relationship between the central position of the wafer W when held by the multi-stage effectors 78a, 78b and the installation position of the sensor 100.

### <Positioning Method in Processing Module>

The transfer arm 71 of the wafer transfer mechanism 70, which is provided inside the transfer module 60 and transfers the wafer W, is inserted into each processing module, such as the substrate processing module 61 or the substrate processing module 62. The transfer arm 71 is inserted in various cases, such as when the wafer W is held and substrate processing is performed in each processing module, or when a dummy wafer is held and the transfer arm 71 is positioned.

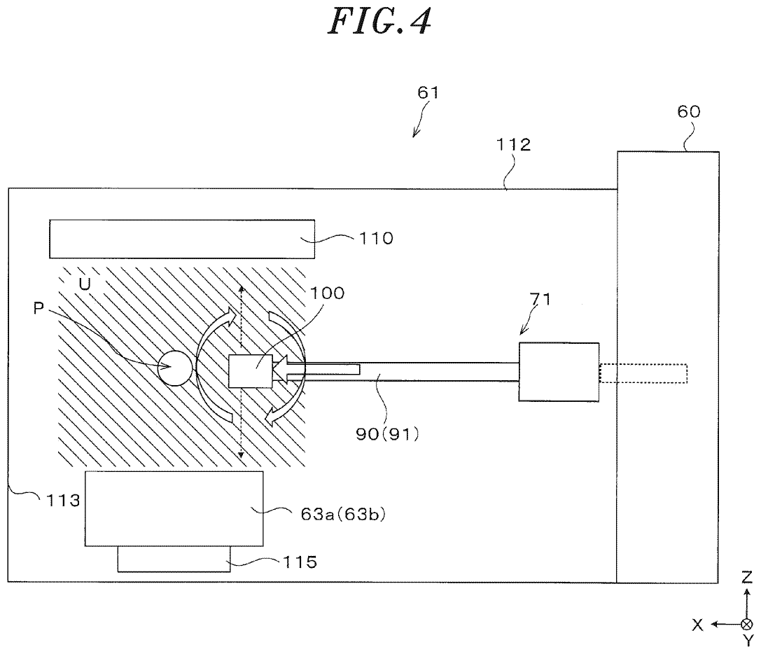

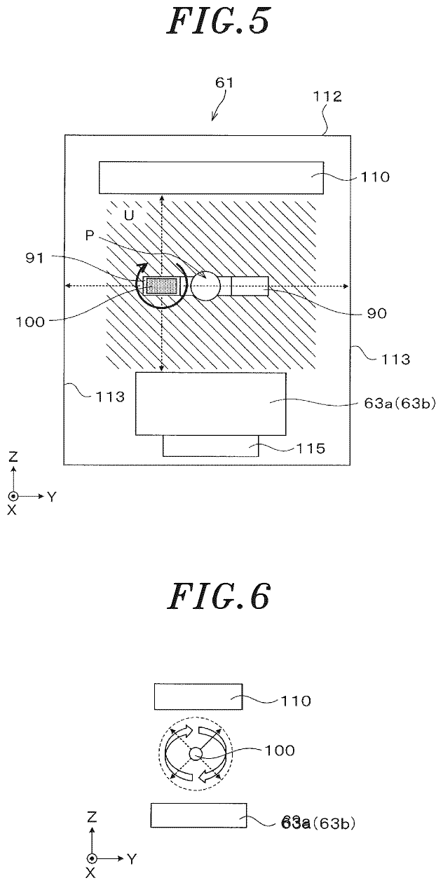

FIGS. 4 and 5 are schematic explanatory views of a positioning method in a processing module, and schematically illustrates the state in which the transfer arm 71 is inserted from the transfer module 60 of the wafer processing device 1 of this embodiment into each processing module, such as the substrate processing module 61 and the substrate processing module 62. In addition, as an example, FIG. 4 illustrates an X-Z cross-sectional view when the transfer arm 71 is inserted into the substrate processing module 61, and FIG. 5 illustrates a Y-Z cross-sectional view thereof, respectively.

As illustrated in FIGS. 4 and 5, the substrate processing module 61 includes a processing chamber 112, which includes a lateral wall unit 113 that configures an inner side surface thereof. The stage 63a (63b) serving as a substrate support is provided at a lower inside of the processing chamber 112. A plate member 110 for supplying gas, for example, is disposed above the stage 63a (63b). In a processing space U surrounded by the stage 63a (63b), the plate member 110, and the lateral wall unit 113, the wafer W is subjected to, for example, the COR processing.

When the transfer arm 71 is positioned, first, the transfer module 60 and the substrate processing module 61 are set under a reduced pressure atmosphere. In this connection, processing gas for, for example, the COR processing may be supplied to the processing space U.

Next, the transfer arm 71 is operated in an X-axis direction (left and right directions in the drawings) to move the position of the sensor 100, and simultaneously, laser scanning is performed while rotating the sensor 100 in the YZ directions (Z radial directions) as shown by the arrows in FIG. 6. This allows measurement of the distances between the sensor 100 and the stage 63a (63b), the plate member 110, and the lateral wall unit 113, and also the outer shape of each member.

Then, based on the measured data, the transfer arm 71 is positioned. The positioning is effective for any teaching position, and for example, the optimum position coordinates of the transfer arm 71 are calculated for the processing space U in which the desired processing is performed on the wafer W. Specifically, the correction position on the XY plane is calculated from the relationship between the center of the stage 63a (63b) on the XY plane and the center of the plate member 110 on the XY plane. In addition, the intermediate position between the stage and the plate member is calculated as the correction position in the Z-axis direction. Then, for example, the ideal central position coordinates of the wafer W are calculated based on the relationship between the central position of the transfer arm 71 and the central position of the wafer W held. The optimum position thus derived (position P in FIGS. 4 and 5) is calculated as the ideal central position of the wafer W.

As such, for example, the ideal central position coordinates of the wafer W with respect to the processing space U are calculated for each processing module such as the substrate processing module 61 or the substrate processing module 62, and the transfer arm 71 is guided.

The aforementioned positioning method of the transfer arm 71 may be implemented as an automatic teaching method under automatic control. In other words, it may be automatically performed under the control of the controller 80 provided in the wafer processing device 1.

In addition, the positioning method may be performed under the same conditions as those used for substrate processing in each processing module, or under different conditions. For example, the positioning of the transfer arm 71 may be performed with the chamber of each processing module open to the atmosphere.

In addition, the substrate support such as the stage 63a (63b) provided in each processing module may be provided with a driving mechanism (not shown) and configured to be movable in a vertical direction (the Z-axis direction in FIGS. 4 and 5) by driving the same. By moving the substrate support, the positional relationship between the plate member 110 and the substrate support may be adjusted. Even for such a configuration, the positioning method of the transfer arm 71 that may be executed at any position within the three-dimensional space as described above is effective.

### Working Effects of Technology of Embodiment of Present Disclosure

As described above, in the transfer arm 71 of the wafer transfer mechanism 70 provided in the wafer processing device 1 of this embodiment, the distance between the sensor 100 and the stage 63a (63b), the plate member 110, and the lateral wall unit 113 is measured, and positioning is performed based on the measured data. This allows the transfer arm 71 to be positioned with any position in the three-dimensional space within the processing chamber of each processing module, such as the substrate processing module 61 or the substrate processing module 62. In other words, the transfer arm 71 holding the wafer W may be guided to any position in the three-dimensional space within the processing chamber, making it possible to mount the wafer W at a desired position.

As in the wafer processing device 1 according to this embodiment, each processing module, such as the substrate processing module 61 or substrate processing module 62, is usually provided in a plural number. Errors occur in the assembly of members in each processing module or chamber, or errors in process conditions occur due to the mounting of separate parts. Specifically, displacement in the height of stage 63a (63b), displacement in the height of the plate member 110, or displacement in the central position of the plate member 110 may result in assembly errors or errors due to the mounting of separate parts, which may cause process differences or increased process startup period. According to the positioning method described in this embodiment, the transfer arm 71 is positioned with an arbitrary position in a three-dimensional space within the processing chamber of each processing module, thereby addressing such an issue.

In addition, the positioning method described in this embodiment may be automatically performed with the wafer processing device 1 under conditions almost the same as the process conditions. In other words, it is no longer necessary to open the wafer processing device 1 to the atmosphere and have an operator perform positioning, which improves positioning accuracy and improves work efficiency.

The embodiments described herein should be considered in all respects as illustrative and not restrictive. The aforementioned embodiments may be omitted, substituted, or modified in various ways without departing from the scope and spirit of the appended claims. For example, the constituent features of the aforementioned embodiments may be combined in any manner. Any such combination will naturally provide the functions and effects of each of the constituent features of the combination, and will also provide other functions and effects that will be apparent to those skilled in the art from the detailed description of this specification.

Furthermore, the effects described in this specification are merely explanatory or exemplary and are not limiting. In other words, the technology according to an embodiment of the present disclosure may provide other effects that will be apparent to those skilled in the art from the detailed description of this specification, in addition to or in place of the aforementioned effects.

For example, in the above embodiment, the wafer processing device 1 is described as having each processing module for performing the COR processing, PHT processing, cleaning processing, and aligner processing on the wafer W, and the substrate processing module 61 and the substrate processing module 62 are illustrated as having two wafers W mounted side by side in the horizontal direction, without being limited thereto. In other words, a so-called batch-type configuration in which three or more wafers W are mounted side by side in the horizontal direction may be used.

What is claimed is:

1. A substrate processing apparatus for processing a substrate, the substrate processing apparatus comprising:
a transfer module for transferring the substrate therein;
a transfer arm disposed inside the transfer module and provided with at least one holding arm for holding the substrate; and
at least one processing module connected to the transfer module, the at least one processing module comprising at least one processing chamber for processing the substrate therein, the at least one processing chamber comprising:
a substrate support having a support surface for supporting the substrate;
a plate member disposed above the substrate support; and
a lateral wall unit configuring an inner surface of the at least one processing chamber, wherein:
a processing space surrounded by the substrate support, the plate member, and the lateral wall unit is in the at least one processing chamber; and
the transfer arm comprises a sensor for positioning the transfer arm based on distances, in the processing space, from the transfer arm to the substrate support, the plate member, and the lateral wall unit.

2. The substrate processing apparatus of claim 1, wherein the sensor is a photoelectric sensor configured to be rotatable about an axis with an extension direction of the transfer arm as the axis, scans an inside of the at least one processing chamber, and measures a distance between the transfer arm and the substrate support, the plate member, and the lateral wall unit.

3. The substrate processing apparatus of claim 1, wherein the substrate support is configured to be movable in a vertical direction inside the at least one processing chamber.

4. The substrate processing apparatus of claim 2, wherein the substrate support is configured to be movable in a vertical direction inside the at least one processing chamber.

5. A positioning method of a transfer arm for transferring a substrate in a substrate processing apparatus, the substrate processing apparatus comprising:
a transfer module for transferring the substrate therein;
a transfer arm disposed inside the transfer module and provided with at least one holding arm for holding the substrate; and
at least one processing module connected to the transfer module, the at least one processing module comprising at least one processing chamber for processing the substrate therein, the at least one processing chamber comprising:
a substrate support having a support surface for supporting the substrate;
a plate member disposed above the substrate support; and
a lateral wall unit configuring an inner surface of the at least one processing chamber, wherein:
a processing space surrounded by the substrate support, the plate member, and the lateral wall unit is in the at least one processing chamber; and
the transfer arm comprises a sensor for positioning the transfer arm based on distances, in the processing space, from the transfer arm to the substrate support, the plate member, and the lateral wall unit.
